(19) United States
(12) Patent Application Publication
(10) Pub. No.: US 2026/0255468 A1
(43) Pub. Date: Aug. 27, 2026

(54) MODULATED PULSED MICROWAVE WAVEFORM IN A POWER SOURCE FOR ACHIEVING A DESIRED ELECTRON ENERGY DISTRIBUTION IN A PLASMA

(71) Applicant: Starfire Industries LLC, Champaign, IL (US)

(72) Inventors: Robert A. STUBBERS, Savoy, IL (US); Ivan SHCHELKANOV, Champaign, IL (US); Brian E. JURCZYK, Champaign, IL (US)

(21) Appl. No.: 19/325,102

(22) Filed: Sep. 10, 2025

Related U.S. Application Data
(60) Provisional application No. 63/693,082, filed on Sep. 10, 2024.

(51) Int. Cl. H05H 1/46

(52) U.S. Cl. CPC H05H 1/463; H05H 2242/22; H05H 2242/24

(57) ABSTRACT

A system configured to provide a non-thermal plasma from a variety of feed gases is described. The system includes a plasma applicator; a feed gas source providing a gas flow to the plasma applicator; a power supply configured to deliver electrical power via a transmission line to an electrode of the plasma applicator; a signal generator configured to provide a drive signal to the power supply; and a controller. The controller is configured to receive at least one input status parameter associated with a quality of plasma delivered by the plasma applicator; and provide at least one parameter value for at least one parameter defining an output signal waveform of the power supply. The at least one parameter value is taken from the group consisting of: duty factor, pulse rate, pulse width, pulse delay, pulse modulation and pulse shape.

### CROSS-REFERENCE TO RELATED APPLICATIONS

This patent application is a non-provisional of U.S. Provisional Application No. 63/693,082 filed September 10, 2024, the contents of which are expressly incorporated herein by reference in their entirety, including any references contained therein.

### AREA OF THE TECHNOLOGY

This disclosure generally relates to a low-temperature (non-thermal) plasma generation. More particularly, the disclosure is directed to controlled operation of power supplied to an electric field generator to cause customized excitation of source gases for plasma generation.

### BACKGROUND

The reaction of N2 and O2 to form NO by a plasma has been known since the Birkeland-Eyde process which preceded Haber-Bosch. The Birkeland-Eyde process eventually fell out of favor because of the challenges for electricity at that time. In addition, the Birkeland-Eyde process suffered from relatively low conversion (<10%) and energy cost (~20 kWh/kg). A primary reason is that the Birkeland-Eyde process was based on an arc discharge which is a high temperature plasma and the conversion of N2 and O2 occurs very close to thermodynamic equilibrium. The equilibrium conversion of N2 and O2 to NO is very limited. For example, at 1500 K, the equilibrium concentration of NO is only 0.1%. The equilibrium conversion is higher as the temperature increases, but the concentration of NO decreases because NO is unstable and dissociates.

Recent interest in developing an alternative process for nitrogen fixation to Haber-Bosch has led to study of low-temperature plasmas for the conversion of N2 and O2 to air. Most of the efforts have focused on traditional plasmas that operate at atmospheric pressure (e.g. DC gliding arc, AC corona, kHz dielectric barrier, etc.) which would result in higher throughput and be more cost-effective to implement as compared to low-pressure plasmas. However, the lowest energy costs found in most of these studies has ranged between ~40 to 300 kWh/kg. In general, there have been several challenges associated with the N2/O2 chemistry. One challenge of generating low-temperature plasmas at atmospheric pressure is that at high pressures, collisions lead to a glow-to-arc transition which transitions a plasma to thermal equilibrium. As the plasma approaches thermal equilibrium, the conversion of N2 and O2 to NO will be once again limited by thermodynamic limitations. A second challenge is that high temperature has other negative effects. The low energy pathway for a plasma process is through vibrational excitation. At high temperatures, vibrational excitation is quenched by collisional energy transfer with the translationally excited molecules. High temperature can also reverse the formation NO through reactions such as N + NO N2 + O. A third challenge is that most atmospheric-pressure plasmas are powered by direct-current (DC) which is simple. However, these plasmas have low densities and are not optimized for energy transfer through vibrational modes, which leads to the high energy cost.

### SUMMARY OF THE INVENTION

Embodiments of the invention are used to provide a system and method for providing a non-thermal plasma from a variety of feed gases. The system includes a plasma applicator; a feed gas source providing a gas flow to the plasma applicator; a power supply configured to deliver electrical power via a transmission line to an electrode of the plasma applicator; and a signal generator configured to provide a drive signal to the power supply; and a controller. The controller is configured to receive at least one input status parameter associated with a quality of plasma delivered by the plasma applicator; and provide at least one parameter value for at least one parameter defining an output signal waveform of the power supply. The at least one parameter value is taken from the group consisting of: duty factor, pulse rate, pulse width, pulse delay, pulse modulation and pulse shape.

The method is carried out by a controller configured for operating a system configured to provide a non-thermal plasma from a variety of feed gases. The system includes a plasma applicator; a feed gas source providing a gas flow to the plasma applicator; a power supply configured to deliver electrical power via a transmission line to an electrode of the plasma applicator; and a signal generator configured to provide a drive signal to the power supply. The method, carried out by the controller, includes receiving at least one input status parameter associated with a quality of plasma delivered by the plasma applicator; and providing at least one parameter value for at least one parameter defining an output signal waveform of the power supply. The at least one parameter value is taken from the group consisting of: duty factor, pulse rate, pulse width, pulse delay, pulse modulation, and pulse shape.

### BRIEF DESCRIPTION OF THE DRAWINGS

While the appended claims set forth the aspects of the present invention with particularity, the invention and its advantages are best understood from the following detailed description taken in conjunction with the accompanying drawings, of which:

FIG. 1 is a system level depiction of a microwave non-thermal plasma jet source where microwave energy is fed into an applicator in accordance with the present disclosure;

FIG. 2 shows a conventional (prior art) microwave plasma source using a magnetron cavity resonator, waveguide and tubular quartz plasma formation region;

FIGS. 3A, 3B and 3C are block diagram including components for solid state microwave plasma source in accordance with the present disclosure;

FIGS. 4A, 4B and 4C are block diagrams including a variation to the corresponding systems of FIGS. 3A, 3B and 3C by providing a pulsed DC power supply;

FIGS. 5A, 5B and 5C are examples and variations on different physical arrangements of plasma applicators in accordance with the present disclosure;

FIGS. 6A, 6B, 6C, 6D, 6E, 6F, 6G and 6H provide various types of sine waves generated by the signal generator under configuration (analog and digital modulation) control of the controller in accordance with the disclosure;

FIGS. 7A and 7B are two series of photographs showing a coaxial plasma jet source in operation under different microwave modulations in accordance with the disclosure;

FIG. 8A is a prior art illustration of the electron energy distribution function (EEDF) for a Maxwellian, Druyvesteyn and Collisional Boltzmann solution for the same average electron energy;

FIG. 8B, prior art, is an illustration of an EEDF for different values of reduced electric field (E/N);

FIG. 9A is a graphical depiction of power and waveform modulation for microwave power delivered to the plasma applicator in accordance with the disclosure;

FIG. 9B shows an illustration of the effect of the tailoring of the EEDF by way of the RF modulation to the plasma in accordance with the disclosure;

FIG. 10A highlights the influence of EEDF as far as non-thermal electron energy contributions into rotational vibrational electronic, direct dissociation and direct ionization pathways in accordance with the disclosure;

FIG. 10B graphically illustrates a narrow window for efficient electron energy transfer into vibrational excitation in accordance with the disclosure;

FIGS. 11A and 11B show ranges for E/N for N2 and CO2 gases to pump energy into different states from electrons in the plasma in accordance with the disclosure;

FIGS. 12A and 12B summarize and depict the effects and advantages progressive vibrational excitation and dissociation for CO2 or CH4 or N2 in accordance with the disclosure;

FIGS. 13A and 13B are block diagrams for potential plasma reactor scenarios in accordance with the disclosure; and

FIGS. 14A and 14B illustratively depict an applicator for CO2 or NO or NH3 production in accordance with the disclosure.

### DETAILED DESCRIPTION OF THE DRAWINGS

The present disclosure is directed to customizing input to a solid-state power amplifier to control the amplitude, delay, ramps or frequency modulation, etc. to control electron energy distribution function (EEDF) in a plasma generated by an electric field produced by the output of the power amplifier. Controlling the EEDF controls where energy flows into gas molecules and atoms. This, in turn, impacts gas temperature, ionization fraction, dissociation, metastable/excited species, etc. Controlling EEDF and controlling application of power spatially and temporally can suppress or enhance streamer formation, can control the effective electric fields in the plasma to promote vibrational excitation to obtain a certain Townsend parameter—for example: (1) provide a direct means to introduce highly-reactive hydrogen (i.e. monoatomic (H•), ionic (H+) and vibrationally-excited H₂(v) species).

By changing duty factor, pulse rate, pulse width, pulse delay, pulse modulation, pulse shape, etc, the discharge characteristics of an output plasma can be substantially altered. Using a power amplifier with fast response facilitates driving an electric field generator for a plasma applicator with an arbitrary waveform for use in a particular plasma application process. Pulsed RF power can also be delivered into the same region from two independent sources, and in this case, it becomes possible to maintain a low density RF plasma with high energy electrons and other desired conditions.

A solid-state microwave-powered non-thermal plasma jet may be operated using a wide range of gases and admixtures, notably 100% hydrogen and an Ar + H₂ mix using high-efficiency (70%) GaN MW amplifiers.

An alternative approach to reacting N2 and O2 are low-temperature plasmas. Low-temperature plasmas are characterized by hot electrons (> 1 eV which is equivalent to ~11,500 K) that drive the chemistry, while the background gas is at a much lower temperature (as low as room temperature). To react N2 and O2, it is necessary to dissociate the very inert N2 bond. In a low temperature plasma, the N2 bond can be dissociated by a variety of modes. The most direct is electrons transferring their energy to N2 through collisions, known as electron-impact dissociation. This requires the energy of the N2 bond, ~9.8 eV. Another mode is vibrational excitation. In this case, N2 is excited through a much lower energy pathway in which the N2 molecule is stepwise excited to higher and higher vibrational modes, known as ladder climbing, until the energy of the vibrationally-excited N2 is close to dissociation and the N2 finally dissociates. Because vibrational excitation of N2 requires much less energy, this reaction pathway to dissociation and subsequent reaction with O2 has been calculated to only have an energy cost of ~2.4 kWh/kg NO.

The presently disclosed arrangement addresses the above discussed challenges for the energy efficient conversion of air to NO. In general, microwave technology offers many benefits for the efficient conversion of gases. In any plasma process, there are many different pathways for energy transfer, and the fraction of energy transferred to the different modes (i.e., ionization, dissociation, electronic, vibrational, and rotational) depends on the ratio of the electric field in the plasma to the gas density, also known as the reduced electric field. Microwave frequencies applied to a gas cause gyration of electrons that enhance their excitation and collision with the gas and thus microwave-powered plasmas are sustained at relatively low reduced electric fields, which enables a large fraction of the energy input to be transferred to vibrational excitation. A lowest energy cost for the conversion of N2 and O2 to NO was a low-pressure plasma powered by microwave. Until recently, microwave operation was challenging at atmospheric pressure. There have been substantial advances in both microwave power generation and understanding of atmospheric-pressure plasmas that have helped realize microwave plasmas at atmospheric pressure.

A coaxial plasma applicator arrangement includes/utilizes high-efficiency GaN solid-state microwave power amplifiers to feed two concentric coaxial electrodes with zonal gas flow, which allows microwaves to propagate into an engineered ‘cut-off’ condition to generate intense electric fields and a plasma to be ignited in a gas flow away from any surface. Controlling the microwave pulse amplitude, frequency, burst envelope and repetition rate, along with localized gas injection, allows for precise tuning of the Townsend (E/N) parameter. The ability to feed arbitrary waveforms into the amplifier for direct modulation of energy flow to the plasma applicator to control the plasma is important.

The coaxial source geometry has the ability to generate very high striking electric fields for plasma formation with rapid response to modulate amplitude, timing, bunching and decay times to tailor the plasma. The inner electrode is a hollow tube that serves both as the center coaxial antenna and for gas flow. Gas can also be fed in the annular spacing between the inner and outer electrode. The antenna can be adjusted for tuning and for the aiming of the plasma at a particular location/direction. The propagation of the microwaves and the gas flow produce a plasma, at the coaxial applicator tip, that forms in free space, avoiding interaction with any surface. The coaxial nature of the applicator tip allows a wide range of microwave frequencies to propagate, enter a cutoff-condition with intense electric fields for plasma generation at atmospheric pressures. In particular for this project, the coaxial gas feed allows tailored gas velocities through the plasma generation zone. Combined with pulsed amplitudes and waveform modulation of microwaves, optimized Townsend parameters can be achieved for vibrational excitation. The plasma output can be quenched to avoid excessive gas heating by either the gas flow through the inner or the outer electrode (or both). There is also the possibility of further cooling the electrodes by water cooling.

Similarly, this technique can also be used for the pyrolysis of methane into hydrogen, CH4 = 2H2 + C, ΔH = 74.5 kJ/mol, the formation of direct ammonia N2 + H2 NH3, the cracking of CO2 into CO and O2, and other pathways with control on plasma EEDF using solid-state microwaves. Similarly, this technique can also be used for discharge pumping of gas lasers, such as CO2, for efficient energy coupling into desired molecular and atomic states.

Previous applications of plasmas in gas conversion have shown that highest energy efficiencies are achieved when E/N is low. While high E/N opens many different excitation pathways, many of these are not relevant to the intended chemistry and thus energy is wasted. In addition, there is an important concept that for molecular excitation, a low-energy pathway exists in which a molecule is vibrationally excited, which only requires a relatively low E/N, and the vibrationally-excited molecules collide with one another, transfer their energy, and gradually populate higher and higher levels. Eventually, the energy of the vibrational level is high enough to allow dissociation. This pathway to dissociation through vibrational ladder climbing requires much less energy than direct dissociation (i.e. electron impact).

Adjustment of the EEDF is important to optimize a reactor. Electrons are mobile and interact in picoseconds to couple energy to molecules and atoms in many ways: vibration, rotation, excitation, translation, dissociation, ionization, etc. The importance in optimizing a plasma processing reactor, e.g. chemical, optical, electromagnetic, etc., is adjusting energy flows and managing the timescales for energy transfer and relaxation. The timescales can span more than 6 orders of magnitude. For example at 1000Torr: (V-T) vibrational-translational time scales may be 2 microseconds, (V-R) vibrational-rotational time scales may be 20 nanoseconds, (R-T) rotational-translational time scales may be 200 picoseconds, and (e-N) electron-neutral collisions 0.2 picoseconds. Specific power electronic tailoring (also with specific reactor designs) can produce superior control of the plasma states. For example at 1GHz the characteristic time (e.g. quarter-wave) is approximately 250ps which overlaps all ranges; and therefore, direct adjustment of electron energy flow into V, R and T states is possible. Compared to an RF system operating at 2MHz having a characteristic timescale 500 time longer there is less opportunity for feedback and control. This is especially important for quantum coupling, anharmonic momentum transfer, plasmonic effects, and plasma-surface interactions for inflight reduction of materials.

Use of a solid-state driver technology or pulsed DC further facilitates control over various electrical parameters including pulse amplitude, frequency, burst envelope, and repetition rate, for precision tuning plasma parameters such as E/N. Adjustments to pulsed operation and/or the control of the microwave energy flow into the reactor can fine-tune and adjust the electron-energy distribution function to inhibit unwanted filamentary arcs or thermal streamers. Programmed (arbitrary) waveforms within the characteristic timescales (e.g. V-T, V-R, R-T) enable adjustment. Such adjustability is beneficial to (up) scaling reactors for higher power density to avoid the plasma transition to thermal run away and excessive gas heating or energy flow into direct impact ionization. Controlling the EEDF, afterglow decay of the plasma between pulses or pulse structures facilitates adjusting chemistry kinetics and reaction rates for selective bond breaking and catalysis, e.g. plasma-gas, plasma-liquid or plasma-solid in the case of flowing mixed materials. This is coupled with gas feed (e.g. laminar flow, vortex flow or turbulent flow) for residence time within the microwave plasma and afterglow zones. Altering the gas admixture can further adjust the collisional energy transfer between molecules, atoms and material surfaces. This is important for reacting with solid material suspended in a gas phase (such as nanoparticles, surface catalysts, reactor walls, etc.

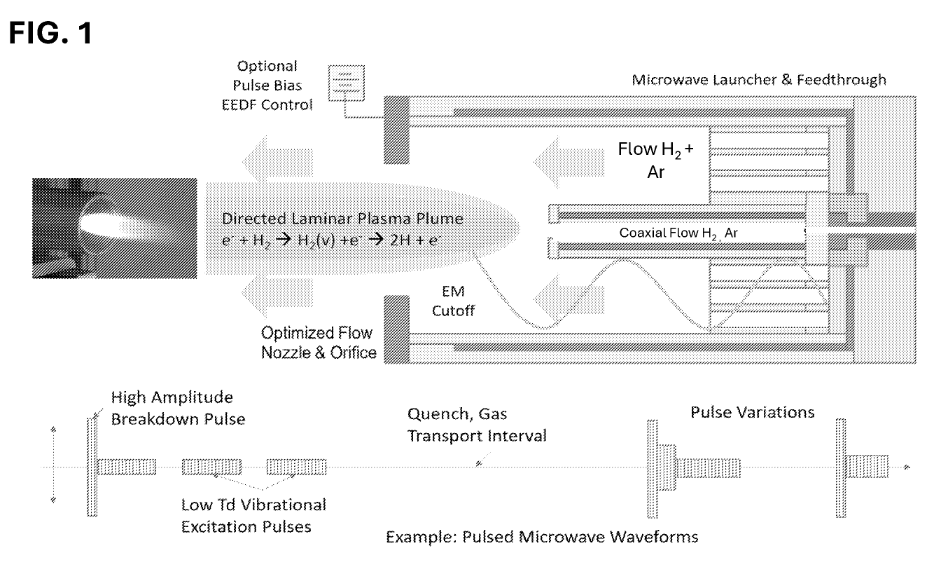

Turning now to the figures, FIG. 1 is a system level depiction of a microwave non-thermal plasma jet source where microwave energy is fed into an applicator where the EM energy propagates until entering cutoff condition causing intense electric field to be created to form a plasma. For atmospheric conditions, where the gas density is large, the electric field must also be high enough to achieve sufficient E/N to cause breakdown and formation and sustainment of a plasma.

The benefit for a solid-state microwave system approach is that the microwave pulses can be modulated on very short timescales from the solid-state amplifier allowing precision control of the microwave power. Examples of adjustable/adjusted parameters include: pulse shape, modulation, amplitude, burst, delay, power, and frequency (among others). Additionally, feedback is provided to the controller, for example, in the form of the following parameters: temperature, flow rate, power, VSWR, optical emission, pressure, electrical current, voltage, and the aforementioned EEDF.

Gas flow through (or around) the plasma applicator can be used to introduce certain reactants, precursors, material to be treated, etc. In the case of FIG. 1, hydrogen gas or a hydrogen and argon gas admixture is flowed through the applicator. Microwave power is applied causing the breakdown of the gas into a conductive plasma. In this example, the plasma plume is directed out of the applicator in the form of a plasma jet. The microwave pulse waveforms are modulated to direct energy into vibrational excitation and dissociation of H2 into 2H radicals with efficiency energy transfer. This allows creation of atomic hydrogen with high efficiency for plasma chemistry. Shown here is laminar flow; however, any flow regime can be used. Control on the electron energy distribution function (EEDF) is key to promote plasma generation, radical formation and control the plasma plume properties, e.g. have broad area, have discrete streamer, have two zone jet, etc.

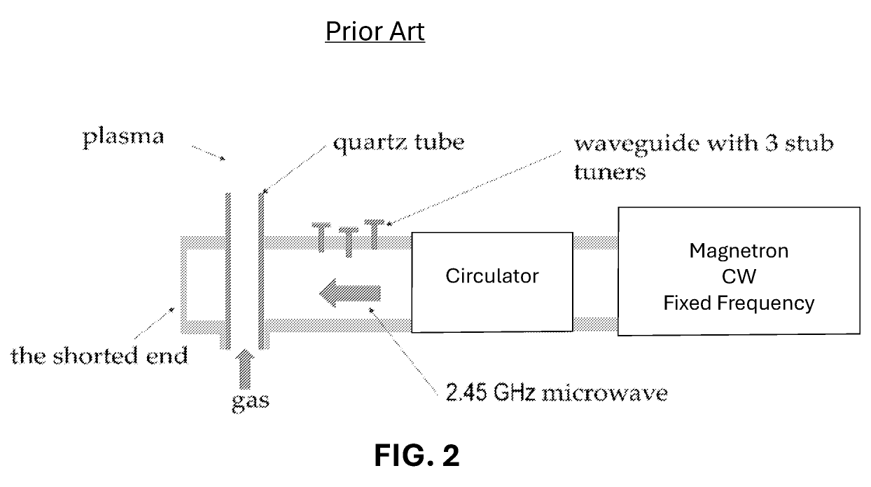

FIG. 2 shows a conventional (prior art) microwave plasma source using a magnetron cavity resonator, waveguide and tubular quartz plasma formation region. The conventional approach with magnetron is limited in frequency (fixed by magnetron design) and CW operation with ability to pulse on long time scales. Power sensing is optional.

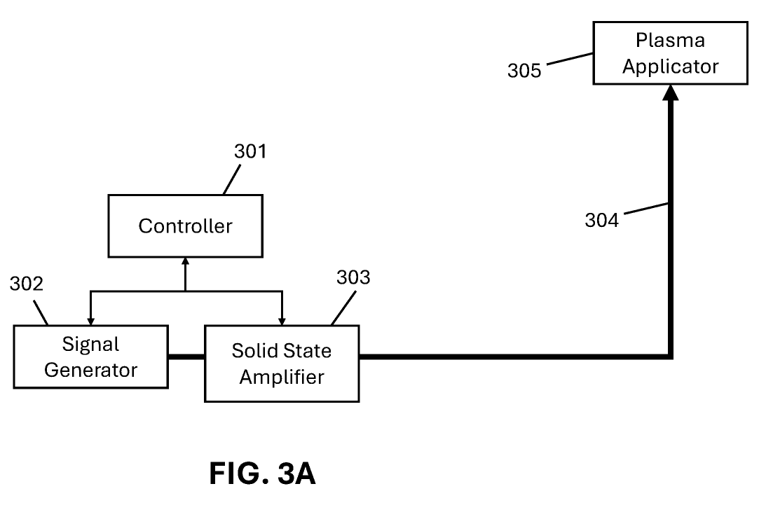

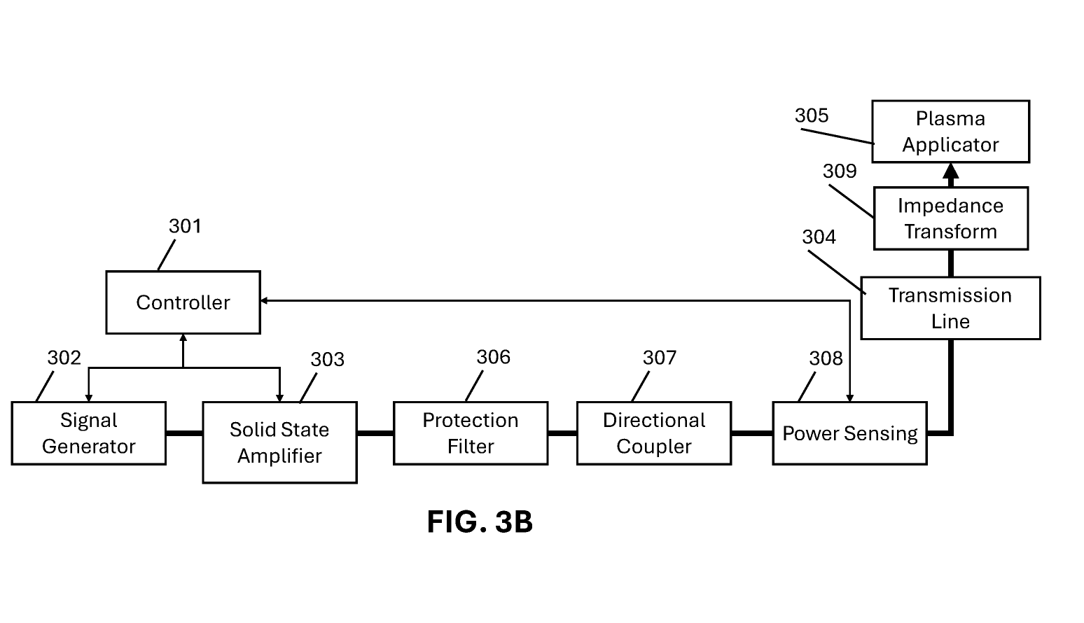

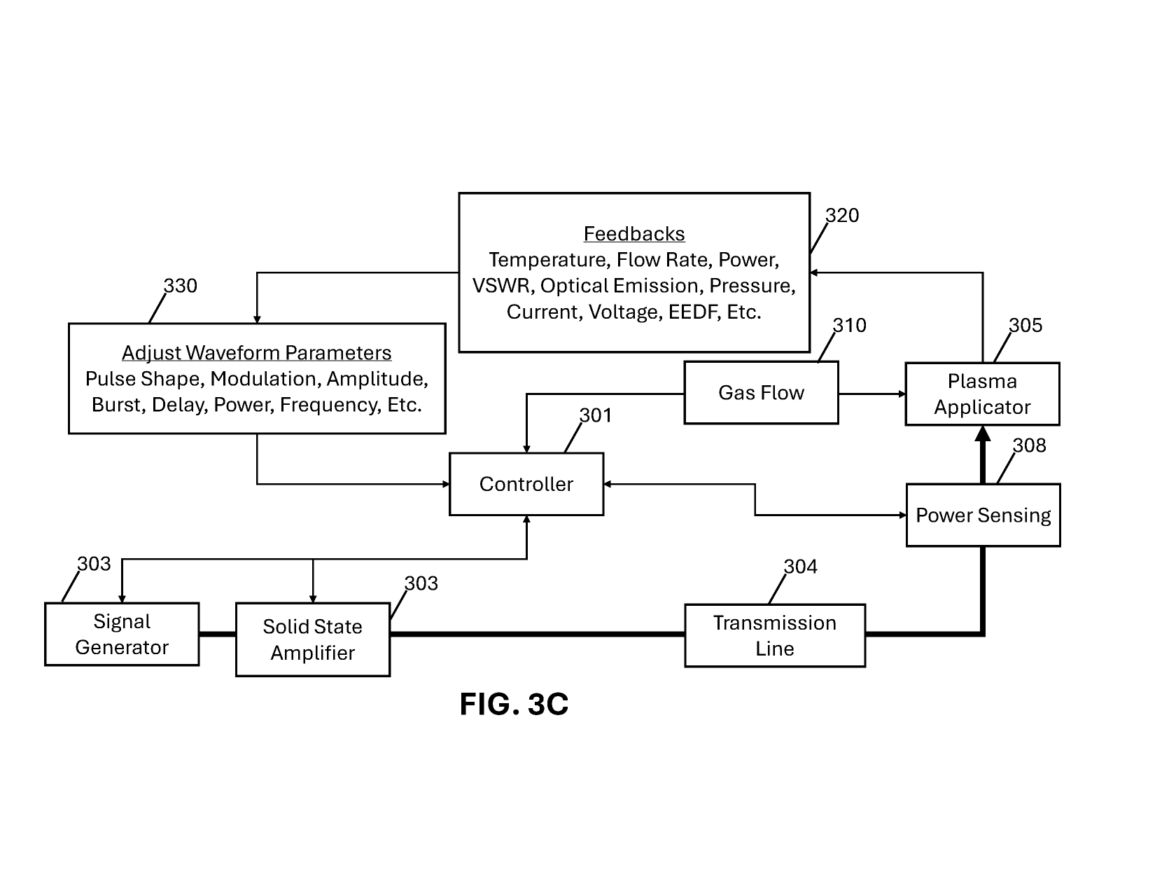

FIG. 3A is block diagram including components for solid state microwave plasma source. The components include: a controller 301, a signal generator 302, a solid state amplifier 303, a transmission line 304 and an applicator 305.

FIG. 3B expands on the basic architecture of FIG. 3A with the addition of: a protection filter 306, a directional coupler 307, a power sensing feedback 308 (to the controller 301) and an impedance transform 309 thereby providing circuit/system component protection and impedance transform functionality in-line for power efficiency.

FIG. 3C further expands on the arrangement of FIG. 3B by addition of: a gas flow system 310 to regulate the plasma properties of the plasma applicator 305, plasma applicator operation feedback sensor signals 320, and waveform control parameters 330 for highly configurable/customizable microwave-based generation of plasma.

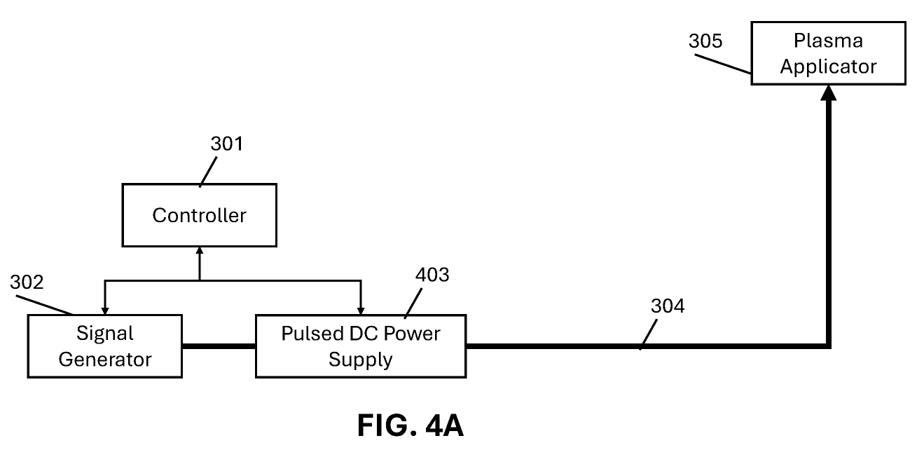

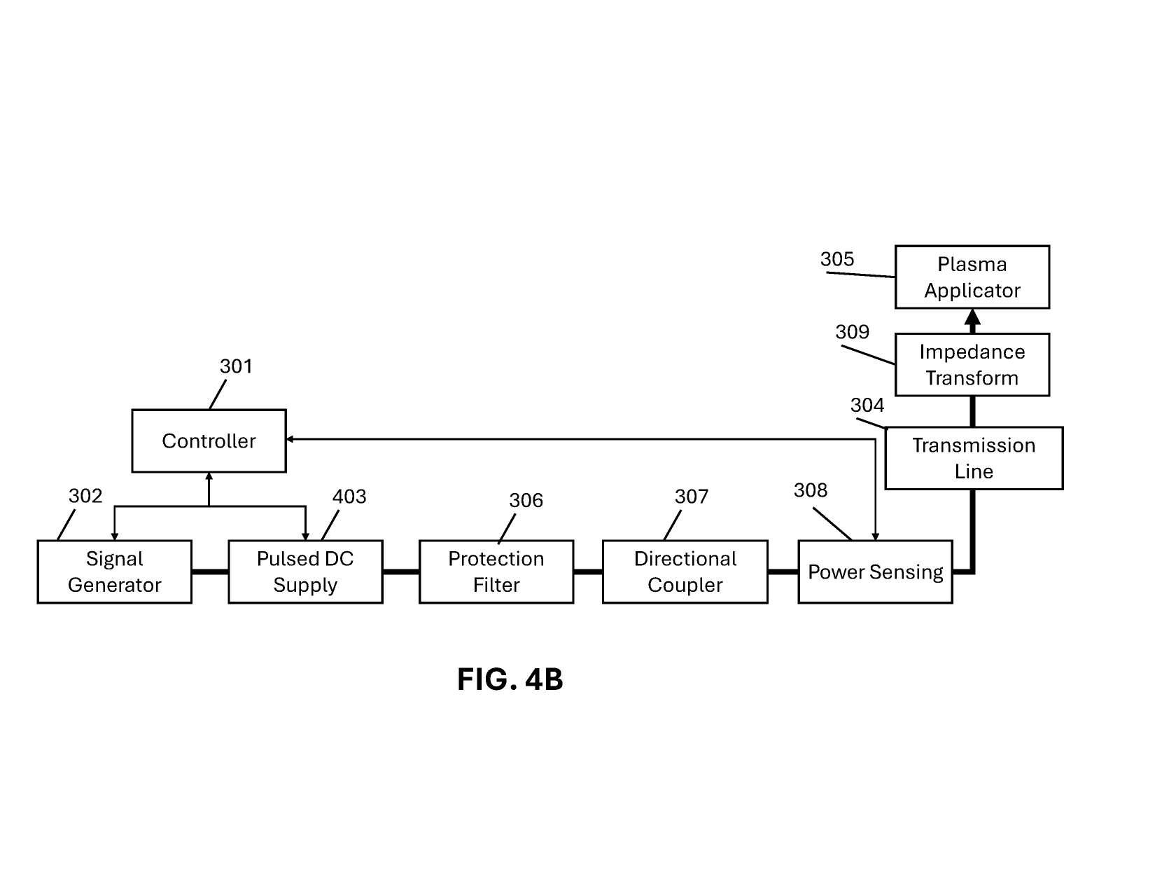

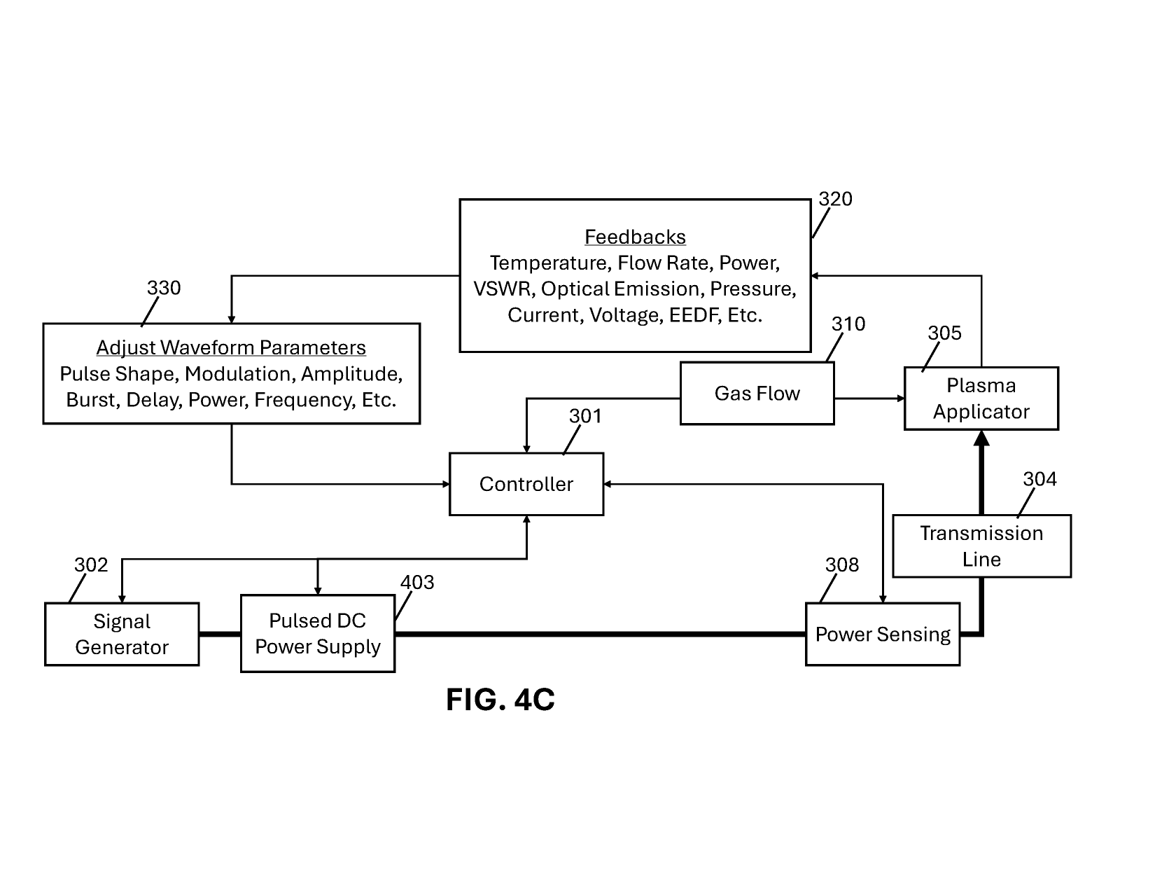

FIGS. 4A, 4B and 4C are further variations to the corresponding systems of FIGS. 3A, 3B and 3C by providing a pulsed DC power supply 403 is provided – as an alternative to the solid state amplifier 303 microwave signal source in the arrangement of FIGS. 3A, 3B and 3C. The pulsed DC power supply 403 can provide arbitrary waveform control. Controlling the waveform at microsecond, nanosecond and picosecond timescales can impact the EEDF control on the relevant collisional and relaxation energy flow processes. The impedance transform 309 is a physical impedance matching element that may be inserted right at the plasma applicator 305 to enable efficient power coupling into the plasma applicator 305. The impedance transform 309 element can be a fixed design to convert the applicator to the transmission line impedance and output of amplifier impedance, e.g. 50 Ohms.

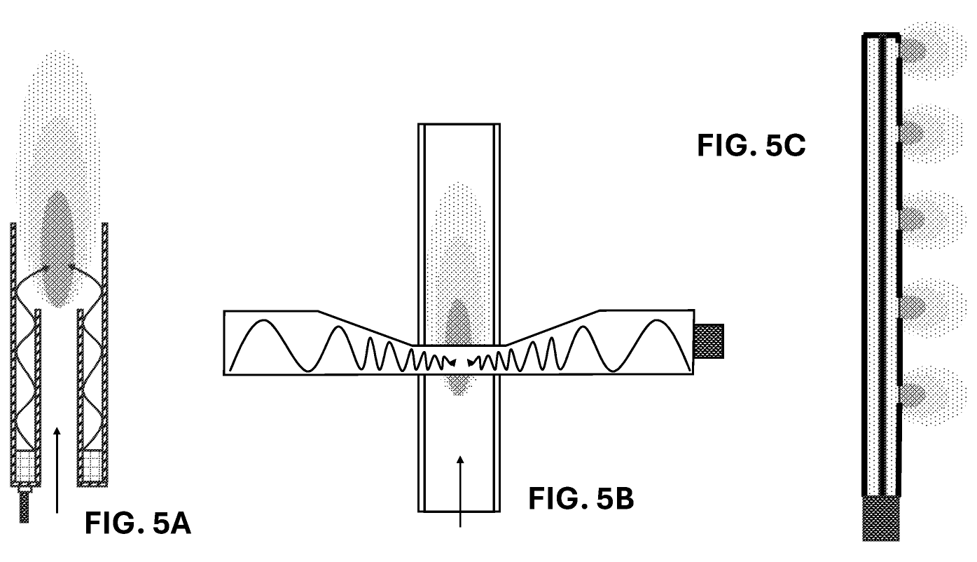

FIGS. 5A, 5B and 5C are examples and variations on different physical arrangements of plasma applicators (plasma applicator 305 in the above discussion). FIG. 5A is a coaxial plasma jet system with on-axis flow. FIG. 5B is a tubular reactor with cutoff waveguide. FIG. 5C is a slotted source for formation of plasma along an axis.

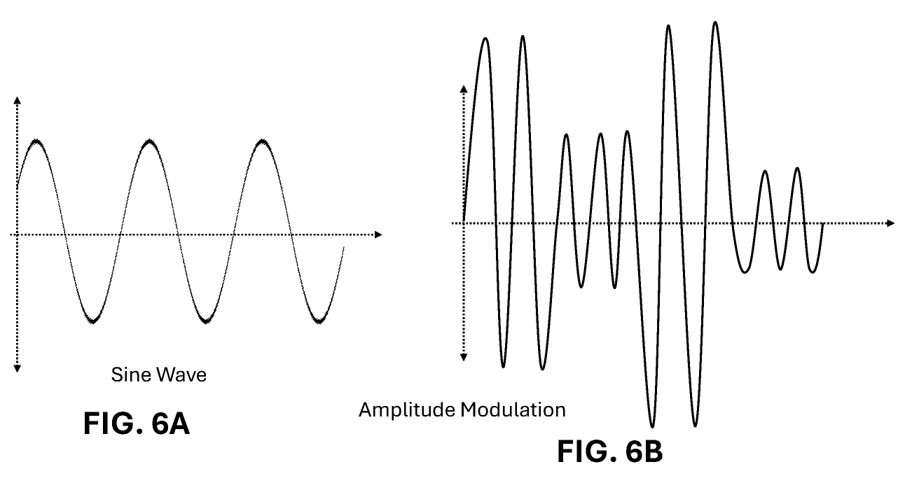

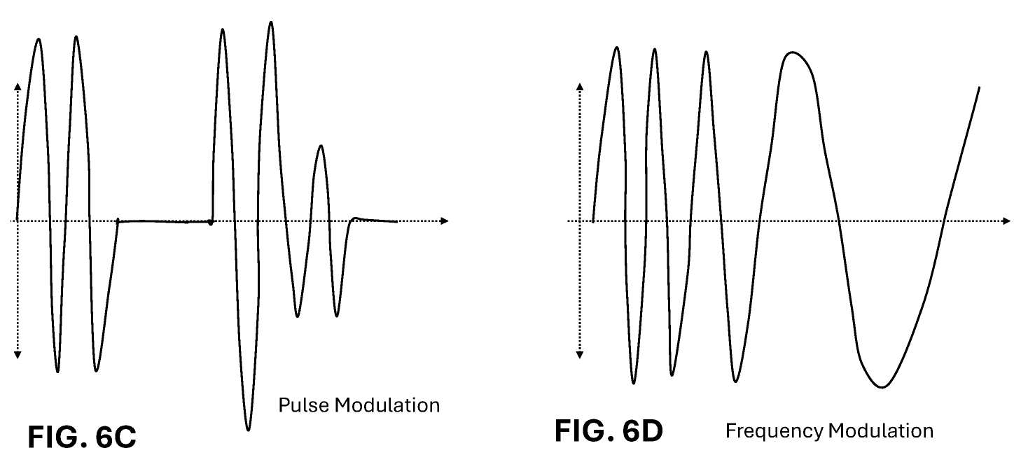

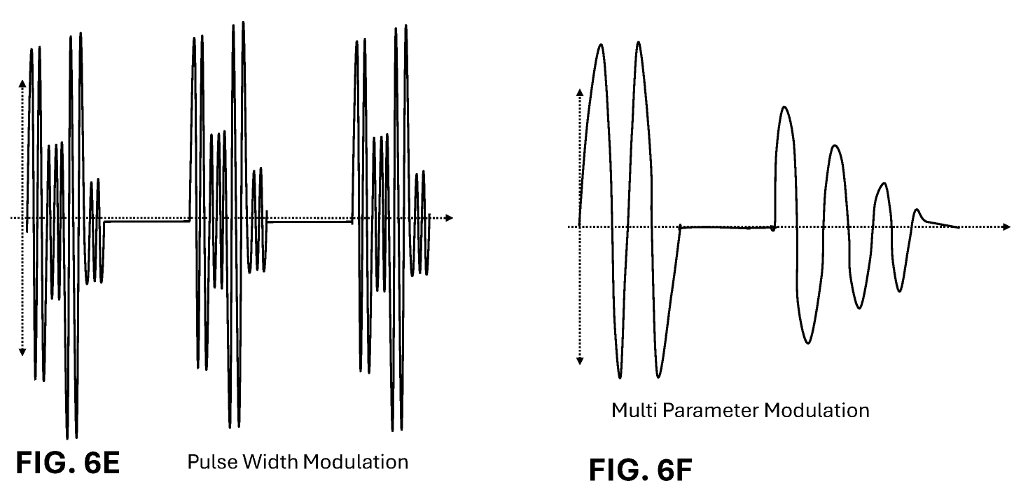

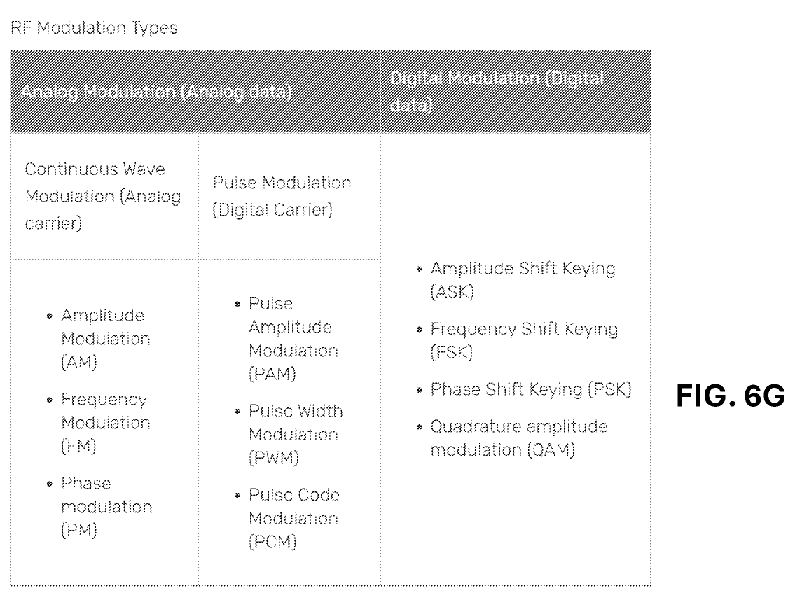

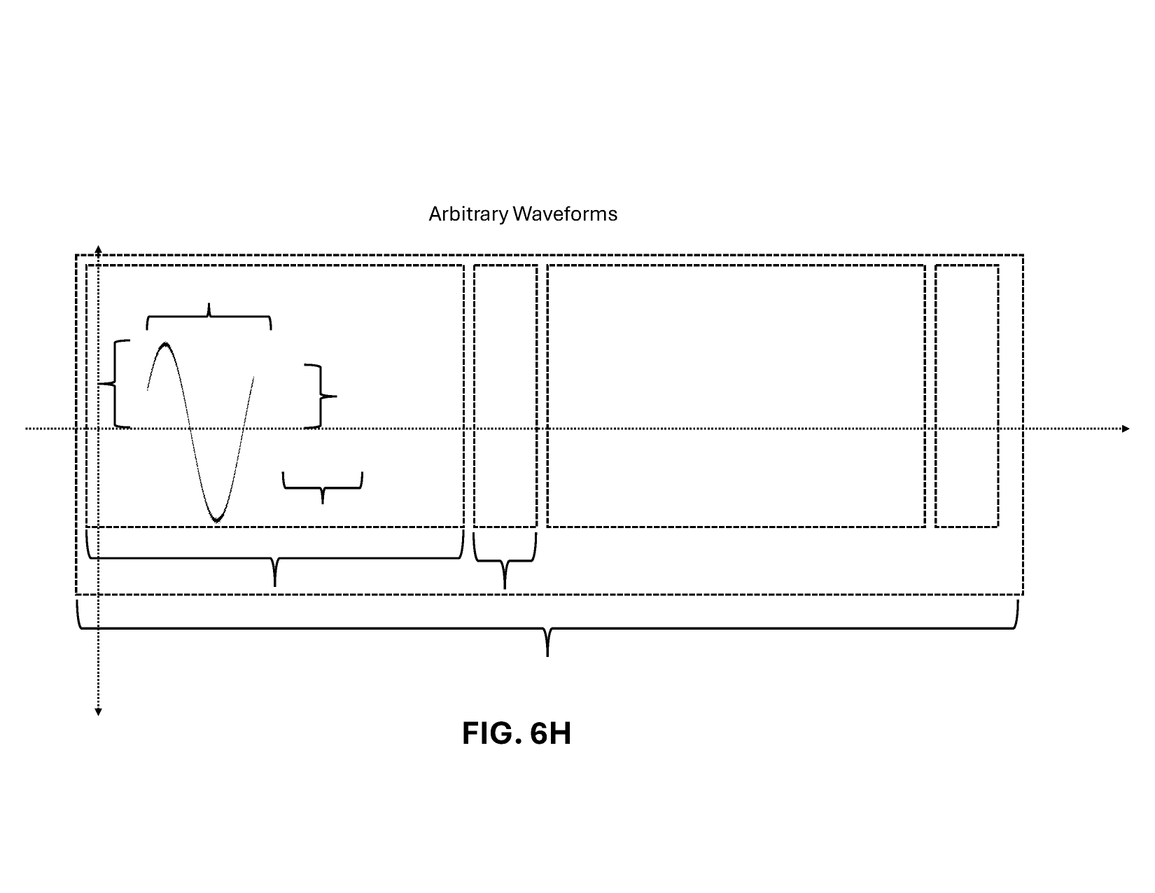

FIGS. 6A, 6B, 6C, 6D, 6E, 6F, 6G and 6H provide various types of sine waves generated by the signal generator 302 under configuration (analog and digital modulation) control of the controller 301. FIG. 6A is an illustration of a sine wave in amplitude vs time for a microwave amplified signal fed into a plasma applicator. The wave moves surface currents in the plasma applicator that give rise to local E and B fields that lead to EM propagation and absorption.

FIG. 6B is an example of amplitude modulation where the microwave signal is amplified differently to yield periods of higher and lower value of power transferred. This has the effect of increasing and decreasing the local electric field and power transmitted to the plasma in the applicator.

FIG. 6C is an example of pulse modulation where the microwave signal can be modulated to give bursts or time dependent behavior. This could allow plasma to form and then decay before being re-energized by the next pulse burst.

FIG. 6D is an example of frequency modulation. This is important because impedance matching of the plasma load and applicator can be accomplished by changing frequency and this can be performed continuously as the plasma source is operating. Changing a reactant gas or flow will have a corresponding change in the plasma impedance, and an adjustment with frequency can improve power coupling and tune the source to high operating efficiency. A change in frequency can also move the zone of plasma formation and plasma operation. This is true for high bandwidth applicators such as TEM coaxial sources.

FIG. 6E is an example of pulse width modulation for envelopes or bursts of a customized waveform. For example, this type of microwave modulation could be used to strike or breakdown plasma, then vibrationally excite plasma, repump the plasma and the continue vibrational excitation to drive molecular dissociation with minimal gas heating or energy into ionization.

FIG. 6F is an example of multi parameter modulation where the amplitude, delay, phase, frequency, etc. can be adjusted on the waveform to achieve the result of simulating the plasma differently to change the electron energy distribution function. For non-thermal plasmas, this is very important to fine tune the energy balance into dissociation or ionization or rotation or excitation, etc. based on the local gas conditions, loss to reactor walls, etc.

FIG. 6G is a table showing common forms of RF modulation.

FIG. 6H is an illustration that arbitrary waveforms can be created and amplified in a solid-state or fast response (tube type) amplifier. This also applies to pulsed DC operation with arbitrary programmable waveforms with ramps, bursts, gaps and other unique pulse forming to impact energy flow into electrons through local E/N and collisional relaxation processes (e.g. excitation, vibration, rotational, electronic, etc.).

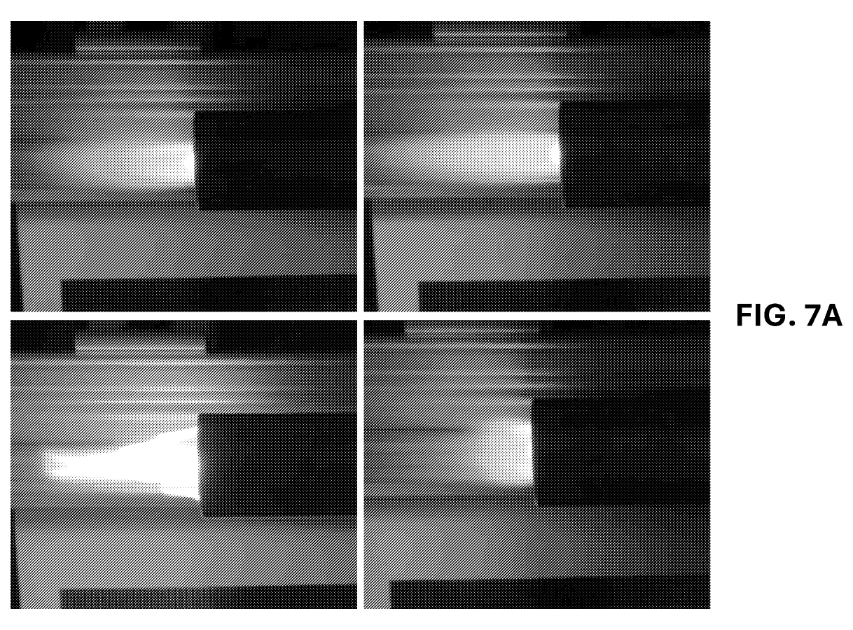

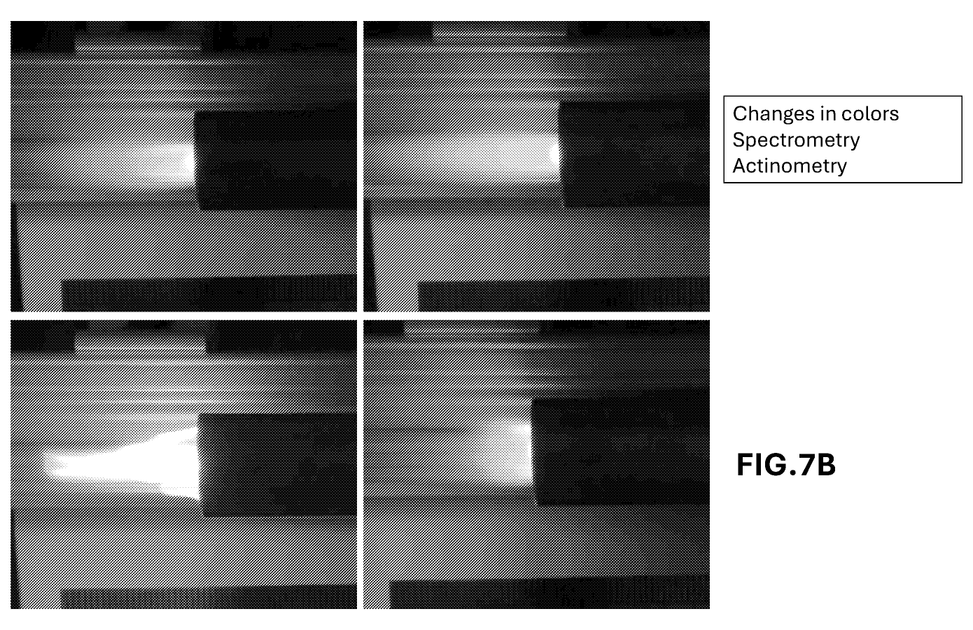

FIGS. 7A and 7B are two series of photographs showing a coaxial plasma jet source in operation under different microwave modulations. Note the structure, color (not visible in black and white image), size and luminosity of the plasma changes depending on the input conditions. For example under CW-like high-power conditions the plasma can become filamentary with high gas temperature. Changing to pulsed modulation with decay time can prevent filament formation and lead to a more diffuse glow and jet effect. Modulating the microwave power can control the EEDF leading to less excitation and cooler plasma, promoting dissociation. These are examples since the parameter space is wide and also depends on gas flow, size, etc.

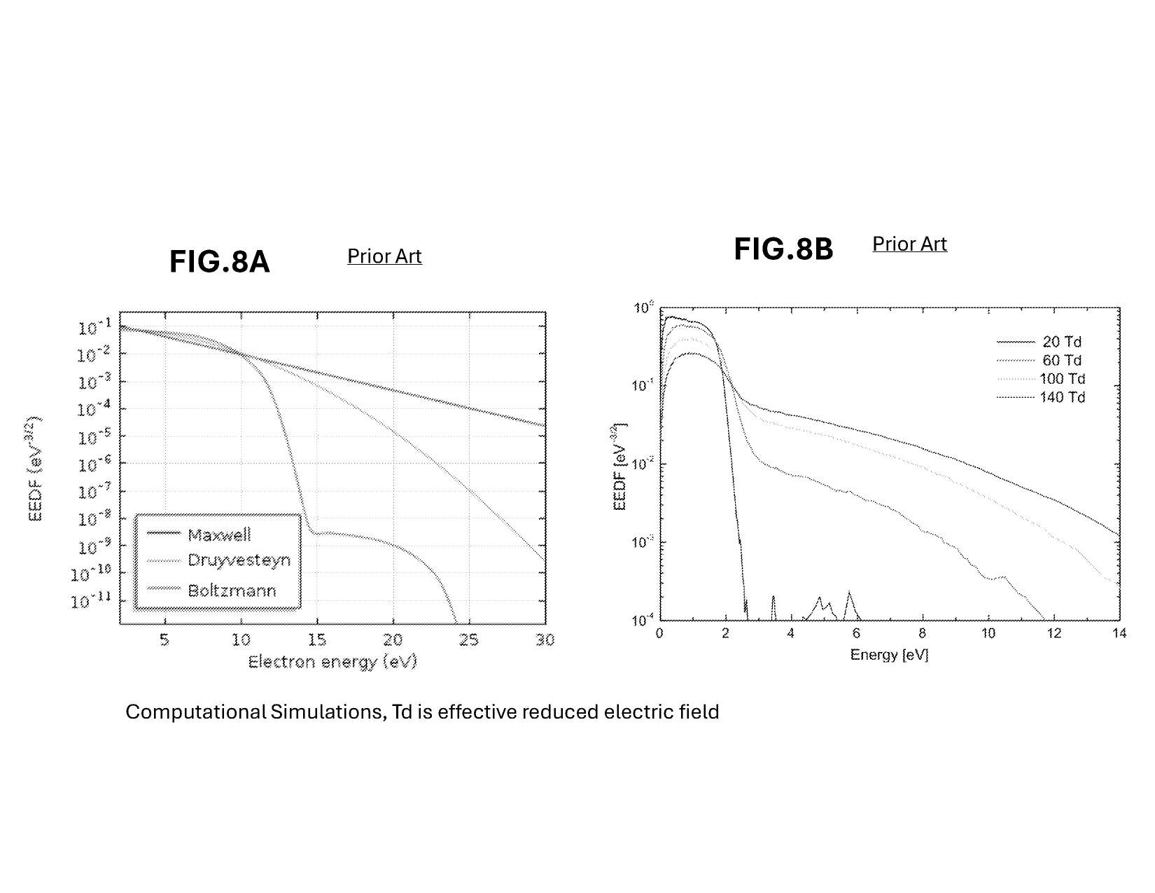

FIG. 8A is a prior art illustration of the electron energy distribution function (EEDF) for a Maxwellian, Druyvesteyn and Collisional Boltzmann solution for the same average electron energy. Depending on the collisional mechanics and the structure of the EEDF, the populations of electrons will change greatly.

FIG. 8B, also prior art, is an illustration of an EEDF for different values of reduced electric field (E/N) which is the electric field divided by the number density of the gas. The number density is a proxy for the collision frequency, mean free path and spacing between atoms/molecules that will have a proxy for the energy that can be gained before collisions for an electron. At every low Td (E/N) the high-energy tail of the EEDF is missing and the electron population is low energy. Whereas at higher values of E/N the population becomes more Boltzmann like before increasing to Druyvesteyn and then Maxwellian.

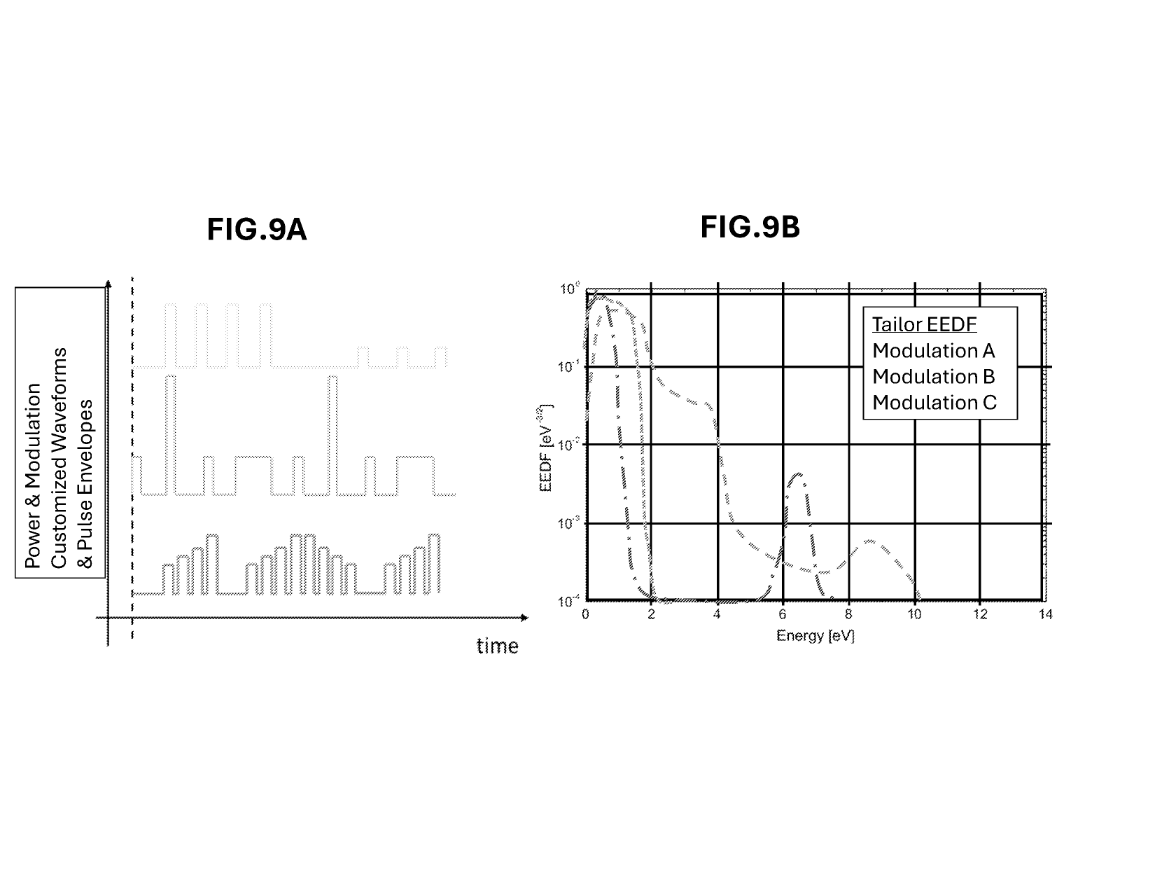

FIG. 9A is a graphical depiction of power and waveform modulation for microwave power delivered to the plasma applicator 305. The figure is intended to depict that adjustments to the EEDF can be made via modulating the input waveform such as introducing delay, plasma afterglow, allowing electrons to diffuse, etc.

FIG. 9B shows an illustration of the effect of the tailoring of the EEDF by way of the RF modulation to the plasma. Adjusting the power delivery and pulse waveform to yield a multi-group EEDF, such as a low thermal population and a small high energy tail, or all below a maximum temperature, etc.

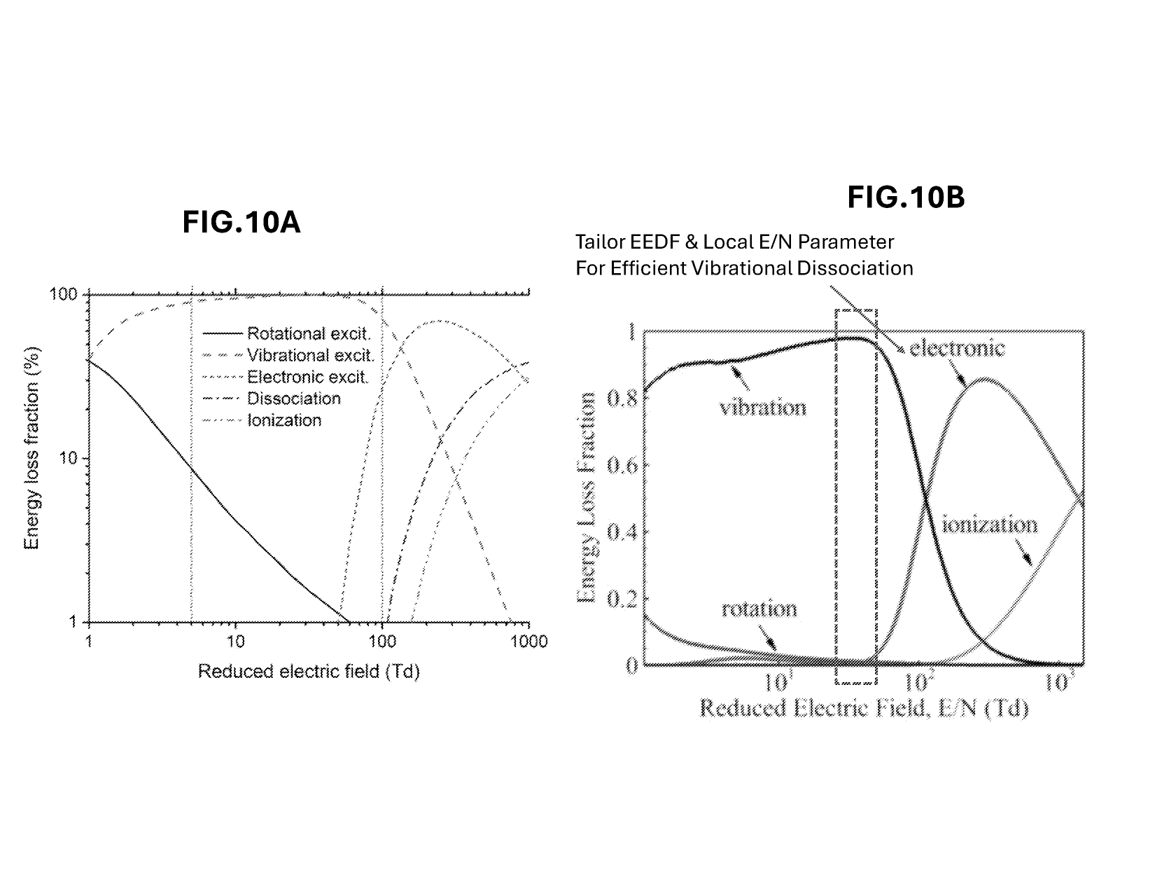

FIG. 10A highlights the influence of EEDF as far as non-thermal electron energy contributions into rotational vibrational electronic, direct dissociation and direct ionization pathways. FIG. 10A is presented as reduced electric field (E/N) showing where the electron energy flows into the gas. For low Td values, the energy goes into rotational heating and vibrational heating. At higher E/N electron energy from impacts go into electronic excitation and direct dissociation and ultimately into ionization at very high Td values. Basically can an electron gain enough energy in the oscillating E field from the microwaves to accelerate high enough to ionize, or is it only going into vibrational excitation.

FIG. 10B graphically illustrates a narrow window for efficient electron energy transfer into vibrational excitation. In this mode for molecular gases, a gas can be vibrationally pumped up in energy until it dissociates. FIG. 10B shows an example effective reduced electric field or effective EEDF needed to achieve this energy transfer.

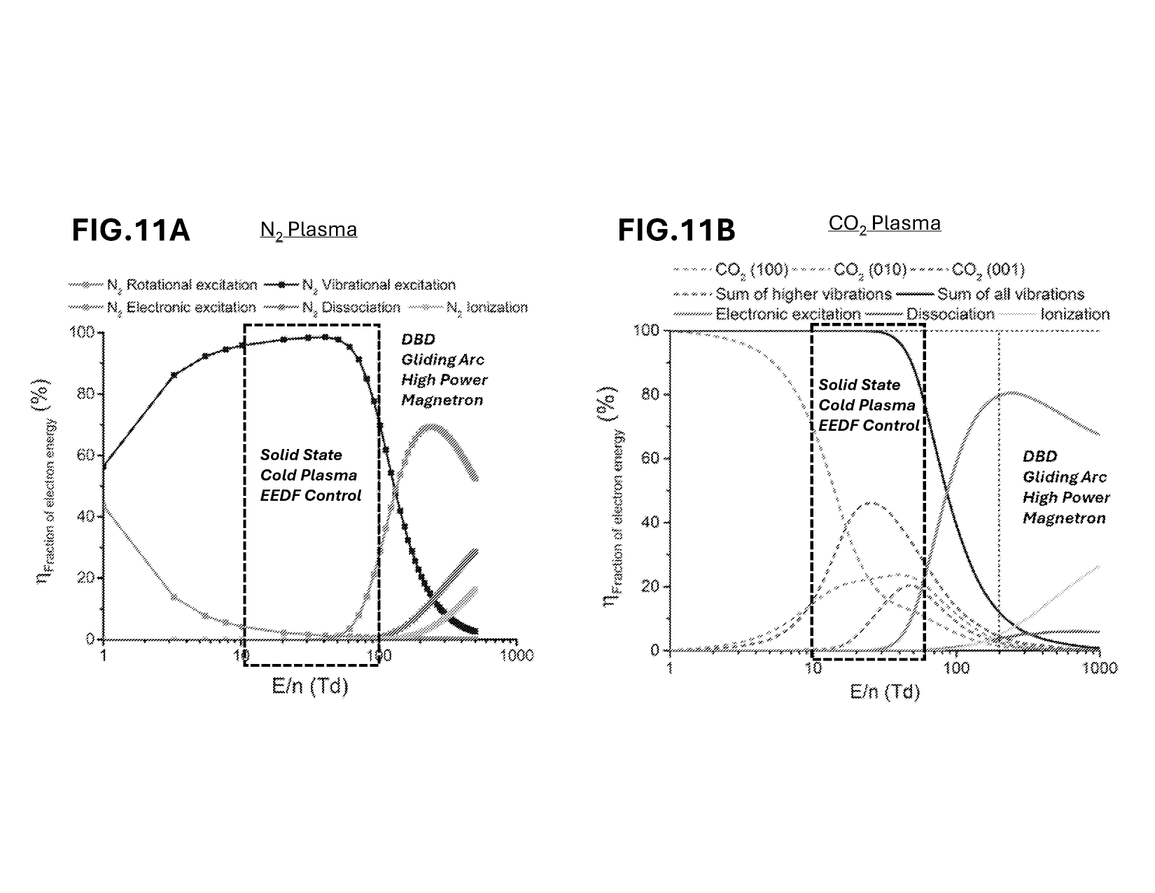

FIGS. 11A and 11B show ranges for E/N for N2 and CO2 gases to pump energy into different states from electrons in the plasma. For CO2 it is more complex since there are three atoms in the molecule, vs the diatomic N2. Note that high power arcs, dielectric barrier discharges, etc. can by far to the right in terms of E/N.

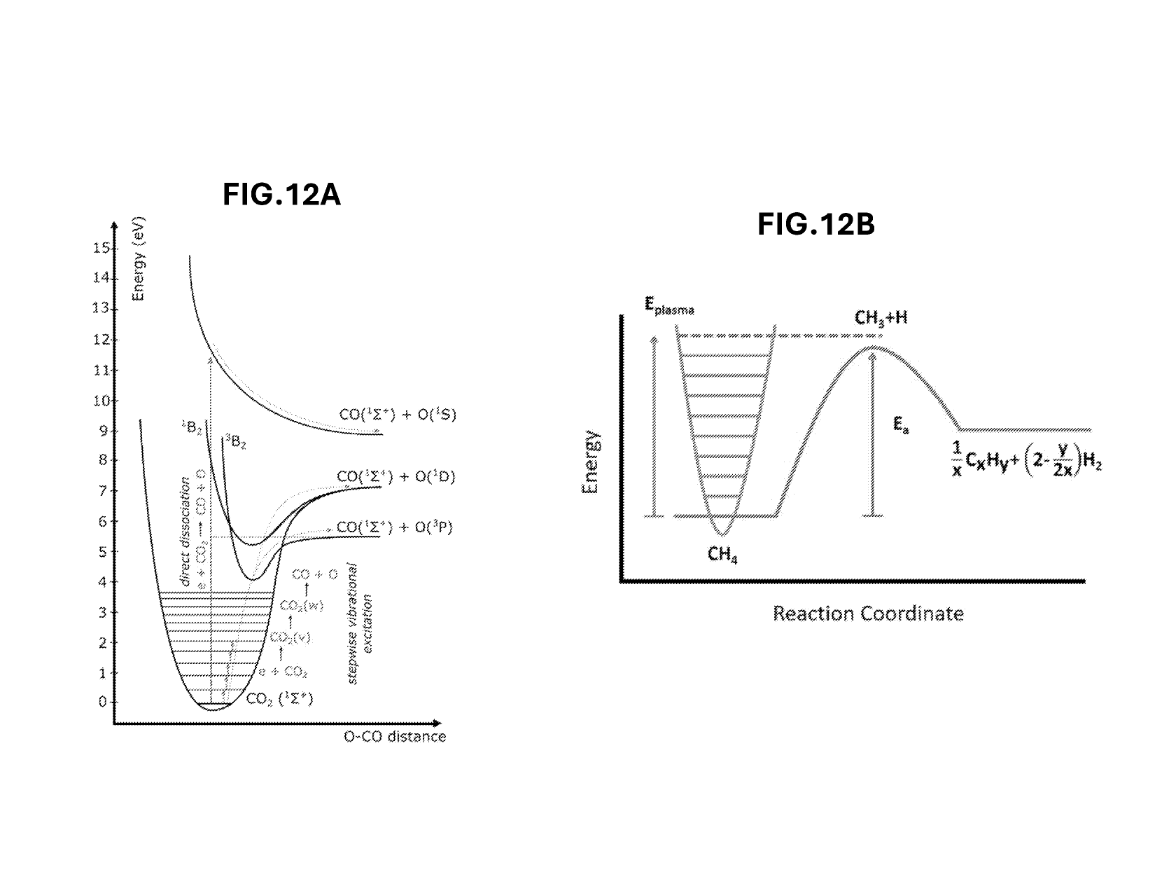

FIGS. 12A and 12B summarize and depict the effects and advantages progressive vibrational excitation and dissociation for CO2 or CH4 or N2. FIGS. 12A and 12B show that direct disassociation for CO2 will take 12eV. However, stepwise vibrational disassociation will only take 5.5eV. This is potentially a large energy savings for plasma chemistry and facilitates maintaining cold plasma without excess gas heating, formation of filamentary arcs, etc.

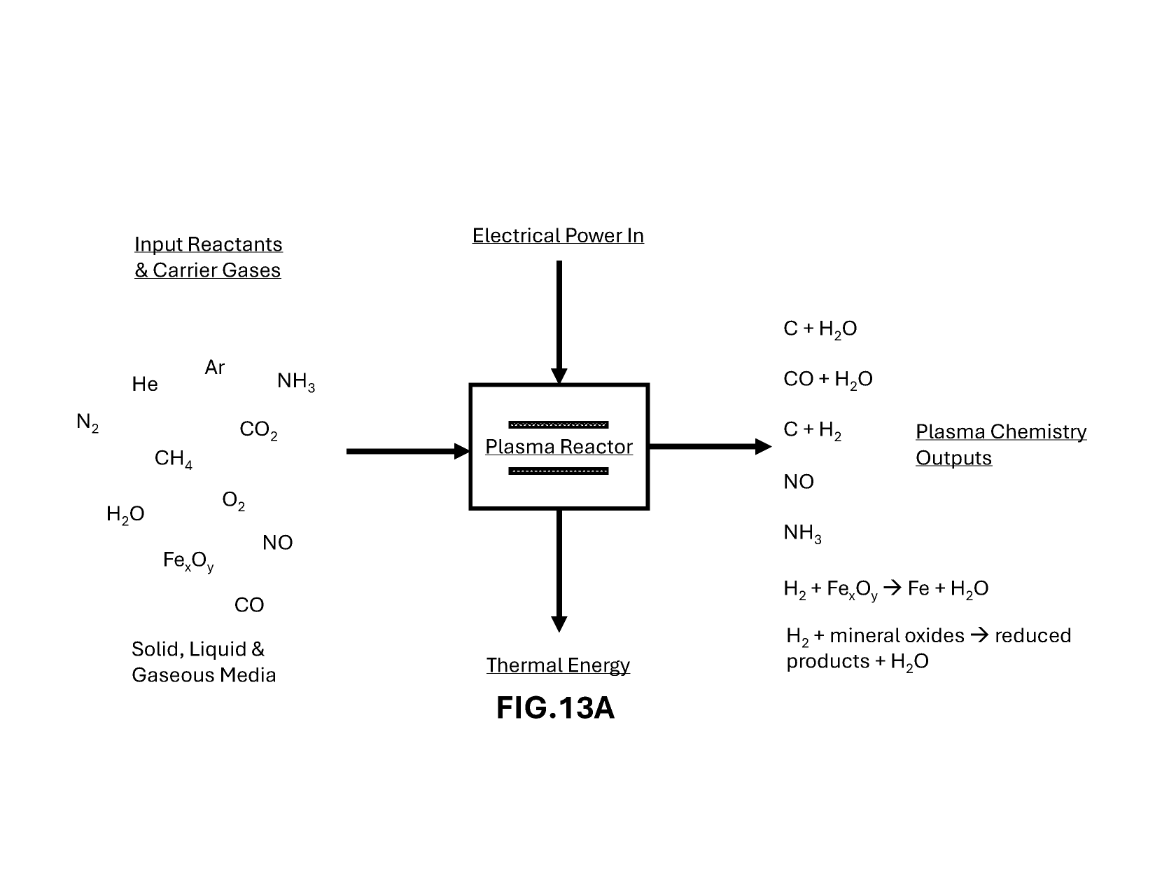

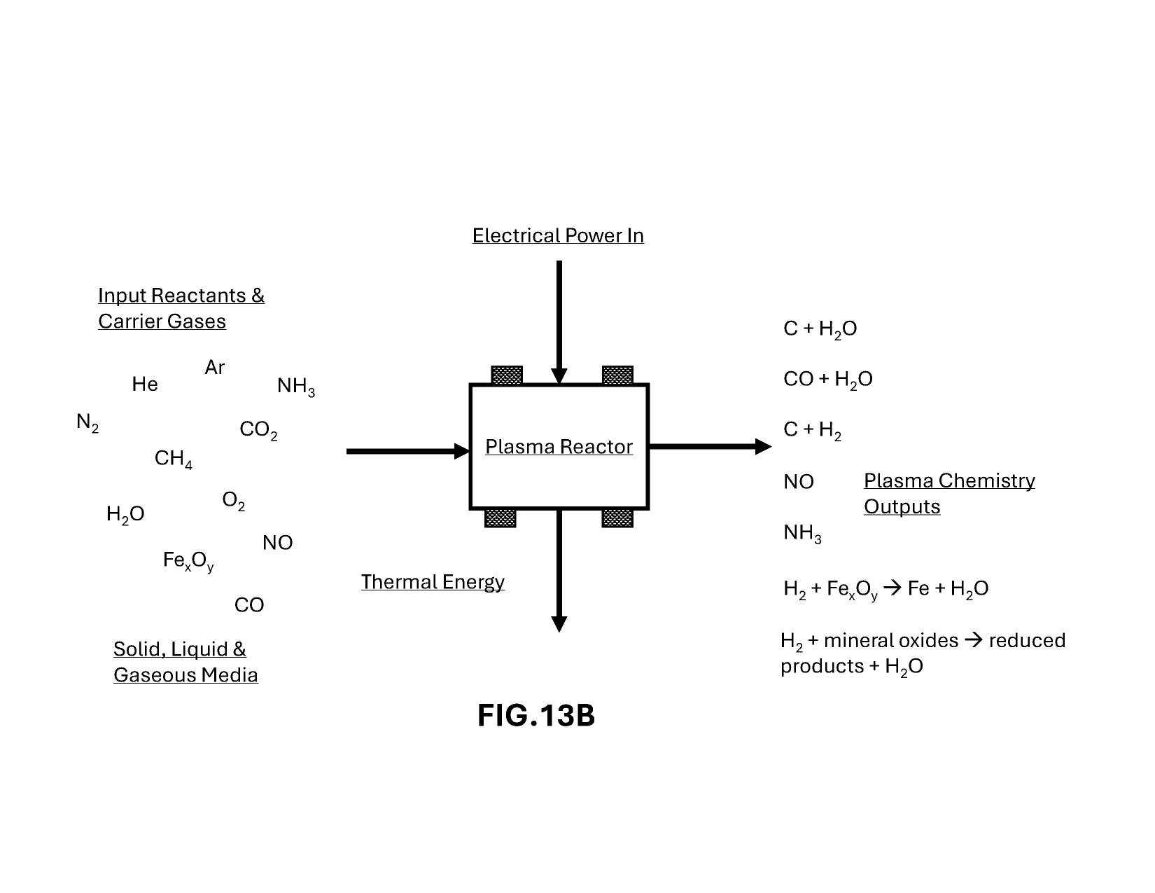

FIGS. 13A and 13B are block diagrams for potential plasma reactor scenarios. This outlines basic inputs, gases, reactants, and output plasma chemistries. Using the solid state microwave plasma system with the controllable EEDF via rapid tuning and adjustment of the pulsed microwave waveforms into the plasma applicator—enables lots of different plasma chemistries and non-thermal, non-equilibrium reaction pathways. For example, we can form ammonia or crack carbon dioxide into CO, or generate carbon back and create hydrogen from methane. In FIG. 13A, the plasma reactor can be a flow-through type. In FIG. 13B, the plasma reactor can be a flow around type depending on the applicator. The process is independent from the reactor type.

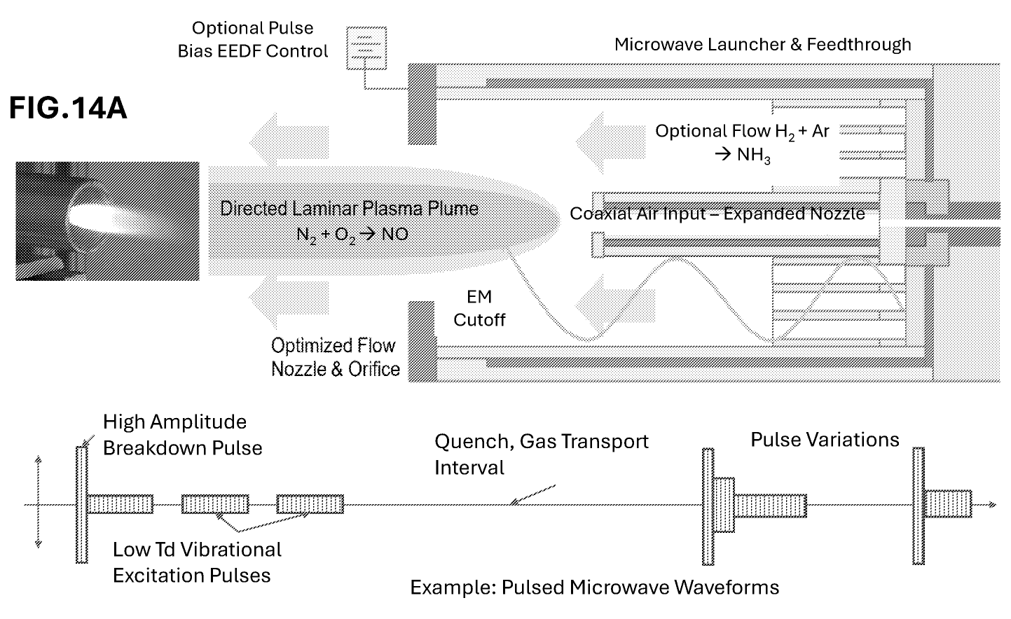

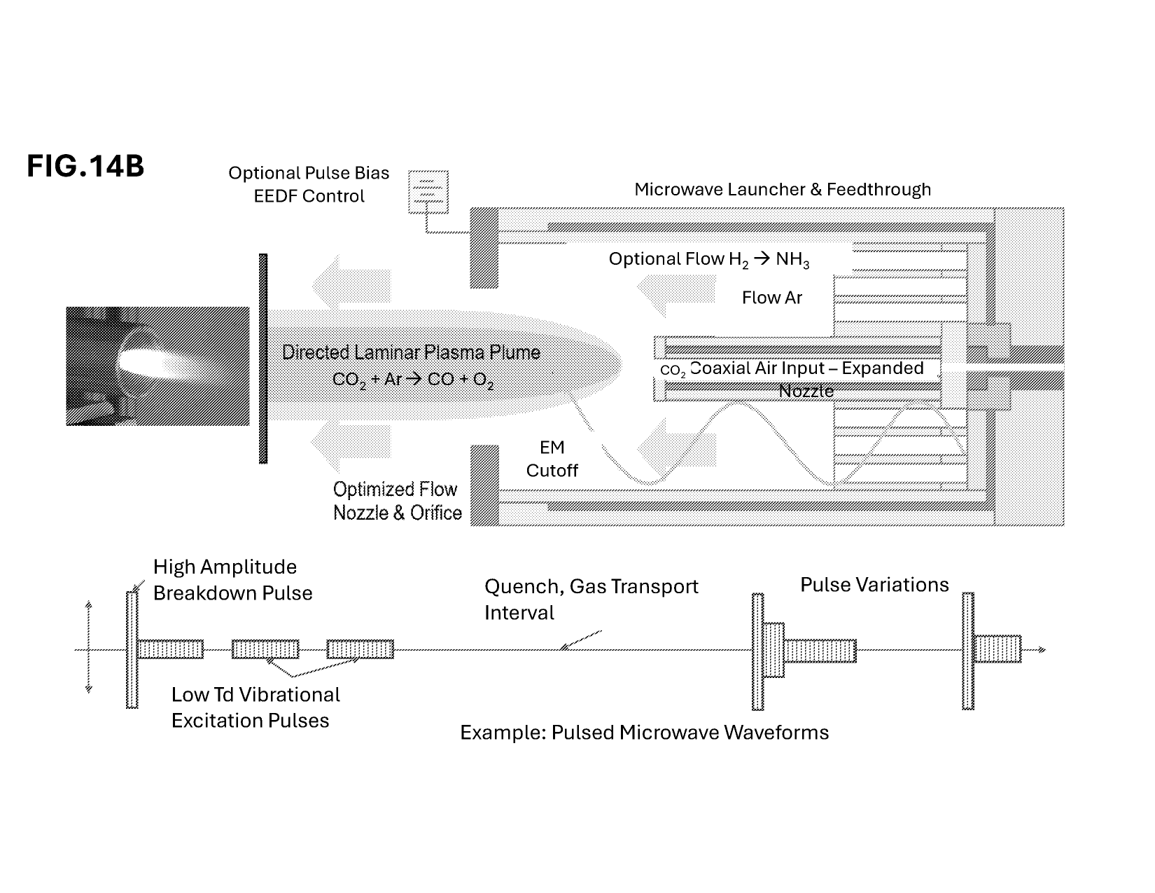

FIGS. 14A and 14B are similar to FIG. 1, and provide a microwave applicator arrangement for CO2 or NO or NH3 production. As shown in FIGS. 14A and 14B, the microwave applicator arrangement has the ability to apply an electrical pulse bias that is applied through an electrode in direct or indirect contact with the plasma to augment and additionally adjust the EEDF. This pulse bias can similarly be directed and controlled by the controller with in accordance with provided feedback parameter values.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A system configured to provide a non-thermal plasma from a variety of feed gases, the system comprising:
a plasma applicator;
a feed gas source providing a gas flow to the plasma applicator;
a power supply configured to deliver electrical power via a transmission line to an electrode of the plasma applicator;
a signal generator configured to provide a drive signal to the power supply; and
a controller configured to:
receive at least one input status parameter associated with a quality of plasma delivered by the plasma applicator; and
provide at least one parameter value for at least one parameter defining an output signal waveform of the power supply,
wherein the at least one parameter value is taken from the group consisting of: duty factor, pulse rate, pulse width, pulse delay, pulse modulation, and pulse shape.

2. The system of claim 1, wherein the power supply is a pulsed power supply.

3. The system of claim 1, wherein the power supply is a solid state amplifier.

4. The system of claim 1, wherein the electrode of the plasma applicator includes a dielectric layer.

5. The system of claim 1, wherein the power supply is directly coupled to the electrode of the plasma applicator.

6. A method carried out by a controller for operating a system configured to provide a non-thermal plasma from a variety of feed gases,
wherein the system comprises:
a plasma applicator;
a feed gas source providing a gas flow to the plasma applicator;
a power supply configured to deliver electrical power via a transmission line to an electrode of the plasma applicator; and
a signal generator configured to provide a drive signal to the power supply; and
wherein the method includes:
receiving at least one input status parameter associated with a quality of plasma delivered by the plasma applicator; and
providing at least one parameter value for at least one parameter defining an output signal waveform of the power supply,
wherein the at least one parameter value is taken from the group consisting of: duty factor, pulse rate, pulse width, pulse delay, pulse modulation, and pulse shape.

7. The method of claim 6, wherein the power supply is a pulsed power supply.

8. The method of claim 6, wherein the power supply is a solid state amplifier.

9. The method of claim 6, wherein the electrode of the plasma applicator includes a dielectric layer.

10. The method of claim 6, wherein the power supply is directly coupled to the electrode of the plasma applicator.
